(19) United States
(12) Patent Application Publication
(10) Pub. No.: US 2010/0286935 A1
(43) Pub. Date: Nov. 11, 2010

(54) Methods for Extrapolating an Energy Measurement

(75) Inventor: Rolf Wendt, Santa Rosa, CA (US)

Correspondence Address: Venture Pacific Law, PC, 5201 Great America Parkway, Suite 270, Santa Clara, CA, 95054, US

(73) Assignee: POWRtec, Campbell, CA (US)

(21) Appl. No.: 12/436,074

(22) Filed: May 5, 2009

(51) Int. Cl. G01R 21/06; G01R 11/32; G06F 19/00

(52) U.S. Cl. 702/60; 324/142

(57) ABSTRACT

A method for generating an energy pulse representative of a unit of consumed energy is disclosed, comprising the steps of: receiving a first energy measurement; receiving a second energy measurement; and if the second energy is greater than or equal to an energy threshold, generating an energy measurement pulse as a function of said first energy measurement, said second energy measurement, and said energy threshold.

### FIELD OF INVENTION

This invention relates to methods for measuring electrical power consumption, and, more particularly, to methods for measuring power consumption by extrapolating from measured energy values.

### BACKGROUND

Electric utility companies use electric meters to track electric usage by customers. These meters track the amount of power consumed at a particular location, such as at power substations, commercial businesses, or residential homes. The electric utility companies then use the information gathered by the electric meters to charge its customers for their power consumption.

Traditionally, electric meters use electromechanical means to track the amount of consumed power. For instance, an inductive spinning disk in the electric meter is commonly used for tracking the amount of power consumed. The spinning disk drives mechanical counters that track the power consumption information. However, the calibration of these conventional meters is quite labor intensive, and even when calibrated, the energy measurements may not be very accurate.

Electronic meters are newer to the market, and are replacing the older mechanical meters. The electronic meters utilize digital sampling of the voltage and current waveforms to generate power consumption information. The power consumption information is displayed on an output display device on the meter.

When a predefined amount of energy is consumed, the output display may also emit an energy measurement pulse, which is analogous to the spinning wheel of an electromechanical meter. However, the energy measurement pulse may not correlate exactly to the predefined amount of consumed energy. For instance, if the pulse is generated at every 1000 wH and two consecutive sampled energy values are 999 wH and 1004 wH, then due to the periodic sampling of energy values and the granularity of the sampling, the pulse may either flash at 999 wH or 1004 wH, either of which would lead to an inaccurate reading of the meter.

Accurate placement of the energy measurement pulse is required in order to correctly calibrate the measurement system. Most electrical meters provide a calibrated pulse output which can be used to provide such a pulse. In complex multi-phase circuits, this requires a communications link as well as a real time pulse indicator, which are costly. In polled value systems, the precise location of the energy measurement pulse is not possible due to quantization errors, which is particularly problematic at low energy levels.

Therefore, it is desirable to provide methods for accurately generating an energy measurement pulse when a threshold energy is consumed.

### SUMMARY OF INVENTION

An object of this invention is to provide methods for calculating an energy measurement pulse interval derived from the energy values at two different times relative to the expected time for a threshold energy, where the pulse interval correlates to a predefined amount of consumed energy.

Another object of this invention is to provide methods for improving the accuracy of an electric meter by extrapolating an energy measurement pulse as a function of the energy measurement data continuously between two sampled quantities.

Briefly, a method for generating an energy pulse representative of a unit of consumed energy is disclosed, comprising the steps of: receiving a first energy measurement; receiving a second energy measurement; if said second energy is greater than or equal to an energy threshold, generating an energy measurement pulse as a function of said first energy measurement, said second energy measurement, and said energy threshold.

An advantage of this invention is that an energy measurement pulse interval that correlates to a predefined amount of consumed energy can be derived from the energy values at two different times relative to the expected time for a threshold energy.

Another advantage of this invention is that the accuracy of an electric meter is improved by extrapolating an energy measurement pulse as a function of the energy measurement data continuously between two sampled quantities.

### DESCRIPTION OF THE DRAWINGS

The foregoing and other objects, aspects, and advantages of the invention will be better understood from the following detailed description of the preferred embodiment of the invention when taken in conjunction with the accompanying drawings in which:

FIG. 1 illustrates a block diagram of the components for an embodiment of the present invention for extrapolating an energy measurement.

FIG. 2 illustrates a flow chart of an embodiment of the present invention for extrapolating an energy measurement pulse.

FIG. 3 illustrates a flow chart for generating a time interval for an energy measurement pulse.

### DETAILED DESCRIPTION OF THE PREFERRED EMBODIMENTS

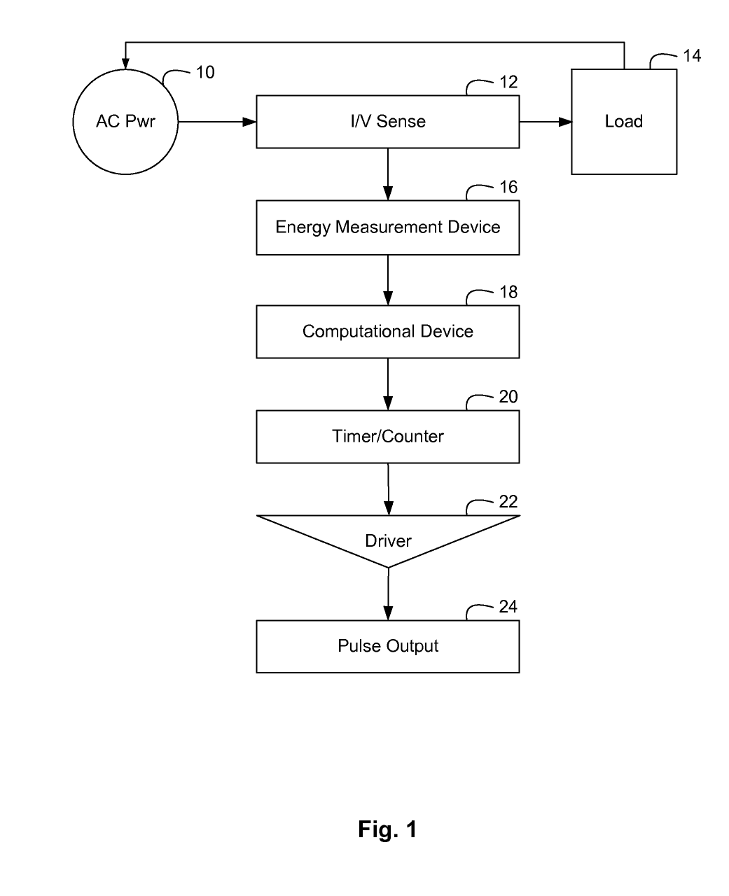

FIG. 1 illustrates a block diagram of the components for an embodiment of the present invention for measuring a consumed energy unit. An alternating current (AC) power source 10 is connected to a current (I) and voltage (V) sensing circuit 12, and a load 14. The I/V sensing circuit 12 can be a shunt that is placed in series with the load 14, so that nearly all of the current to be measured will flow through the I/V sensing circuit. The voltage drop across the shunt is proportional to the current flowing through it since the resistance of the shunt is known. A millivolt meter connected across the shunt can be scaled to directly read the current value.

The I/V sensing circuit 12 outputs the sensed data to an energy measurement device 16. The energy measurement device 16 collects the data of the current passing through the I/V sensing circuit 12, and can calculate the energy measured from this data. The information collected by the energy measurement device 16 is used by a computational device 18 to interpolate the data and to calculate an amount of time to wait before generating the energy measurement pulse. A timer/counter 20 is used to wait the calculated amount of time before triggering the energy measurement pulse. Once triggered, a driver 22 drives the pulse to generate the energy measurement pulse 24, which is the output.

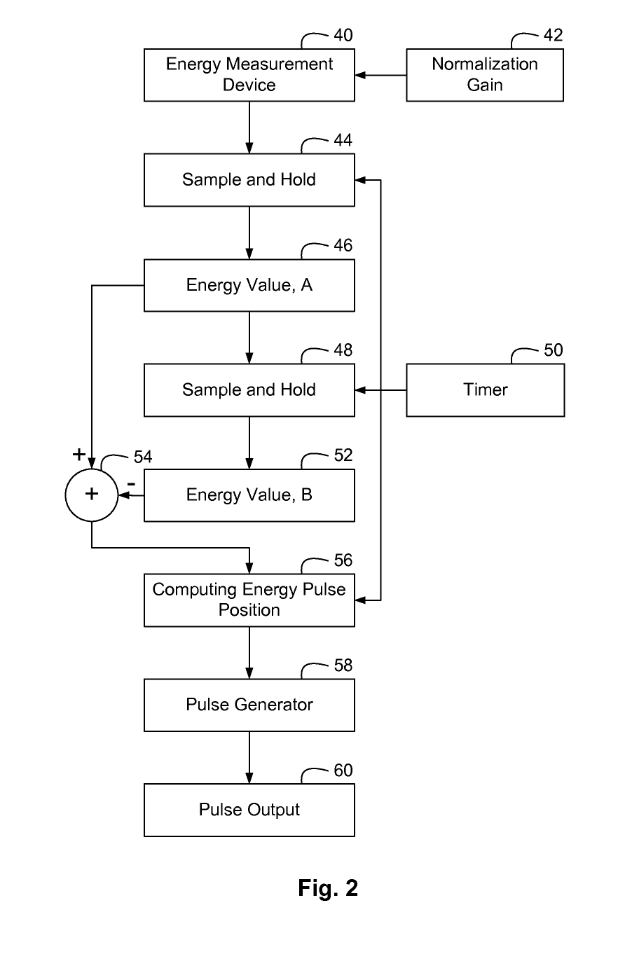

FIG. 2 illustrates a flow chart of a method of the present invention for extrapolating an energy measurement pulse. Variance in the energy readings of an energy measurement device 40 can be adjusted by a normalization gain 42. Once the energy measurement device 40 is adjusted, a sample and hold circuit 44 can receive an energy value, A, at a sampled time, t_{A}, from the energy measurement device 40. For each sampled time, an energy value is measured and stored in the sample and hold circuit 44.

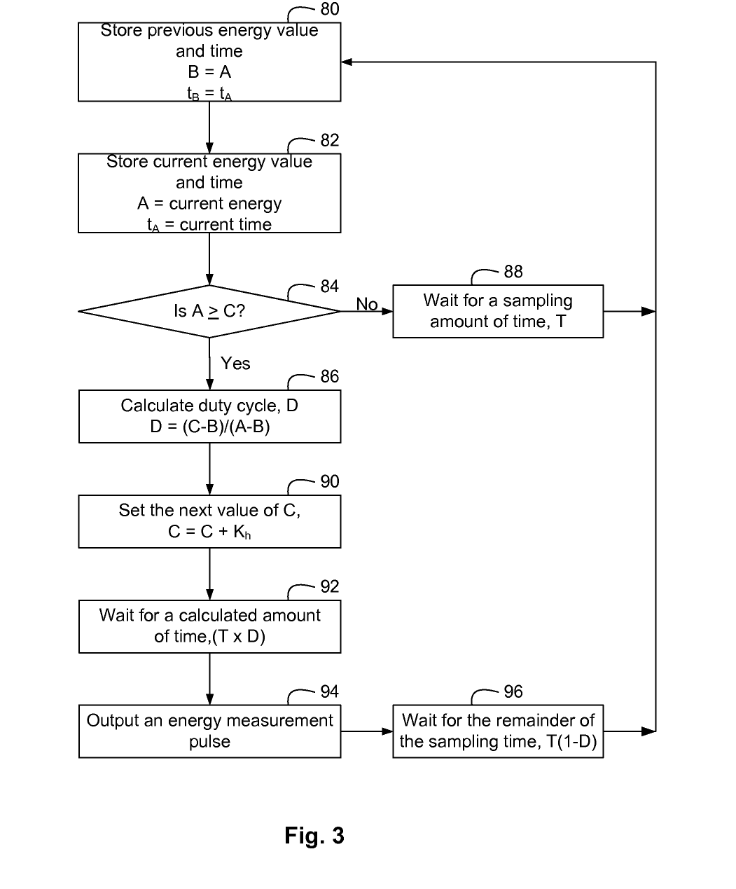

When a timer 50 triggers the next sampling, the energy value, A, is used to compute an energy measurement pulse position 56. An energy value B at a sampling time, t_{B}, which is stored in a sample and hold circuit 48, is also used in computing the energy measurement pulse position 56. The energy measurement pulse position can be interpolated using the values of A and B. The algorithm for extrapolating the energy measurement pulse position is explained in detail in FIG. 3.

Referring to FIG. 2, the interpolated energy measurement pulse can be translated to an amount of time to wait before generating an energy measurement pulse that corresponds to the interpolated energy measurement pulse. The timer 50 can be used to wait for that amount of time. After the amount of time has elapsed, a pulse generator 58 is triggered to generate the energy measurement pulse 60.

In the next sampling, the energy value A is stored in the sample and hold circuit 48, and designated as an energy value B. A new energy value can then be received from the energy measurement device 40, and stored by the sample and hold circuit 44, wherein this new energy value is designated as energy value A. Thus, the process can restart by using the values A and B for computing the next energy measurement pulse. The energy values A and B can be also considered as energy values, energy (n) and energy (n-1), at time tₙ and tₙ₋₁.

FIG. 3 illustrates a flow chart of an algorithm for generating the time interval for an energy measurement pulse. In order to interpolate the energy measurement pulse for a fixed amount of consumed energy, Kₕ, an energy reading, A, at a current time, t_{A}, can be compared with a threshold energy, C, also referred to as a trigger value 84. The energy C is the value at which the energy measurement pulse should be triggered when that amount of energy is consumed. If the value of A is not greater than or equal to the value of C 84, then an amount of time, T (herein referred to as a sampling time), is waited before taking the next energy value sample 88. In selecting a value for the sampling time, T, it is preferred that such sampling time be sufficiently small such that it may cover the acceleration in the energy value A between two sampling times.

After waiting the sampling time, T, a current energy value is sampled at a current time. The previous energy value, A, is stored and redesignated as an energy value, B, at its corresponding time, t_{B}, 80. The current energy value is stored as the current energy value, A, at a current time, t_{A}, 82. The periodic sampling and resetting of the energy value A and the energy value B can continue in a loop until the condition when the energy value A is greater than or equal to the energy value C is reached 84.

When the energy value A is greater or equal to the energy value C 84, a duty cycle D is calculated 86, where

D=(C−B)/(A−B) (1)

The duty cycle predicts when the next energy measurement pulse should be generated. After the duty cycle is calculated 86, the energy value C can be set to a new value where that value is the value of C plus the next amount of energy to trigger the next pulse, Kₕ, 90. The Kₕ value is the amount of energy that is represented when two consecutive energy measurement pulses are generated, and it is a constant.

Once the duty cycle is calculated 86, an amount of time equaling the sampling time, T, multiplied by the calculated duty cycle, D, is waited 92 before generating an energy measurement pulse. Once this amount of time is reached, the pulse can be generated and outputted 94. The remainder of the sampling time, T(1−D), is waited 96 before sampling the next energy value. After the remaining time has elapsed, then the previous energy value of A is designated as the energy value B at the sampling time t_{B} 80, and the next energy sample is received and designated as the energy value A at a sampling time t_{A} 82. Subsequently, this process continues in this manner, constantly accumulating more energy A and generating an energy measurement pulse when the energy value A is greater than or equal to the energy value C.

### EXAMPLE

Assuming an energy value C is initially set at 1000 kWh, an energy value B is 999 kWh, and an energy value A is at 1004 kWh, then the condition that the energy value A is greater than or equal to the energy value C is true. Next, Equation (1) is used to calculate the duty cycle; thus the duty cycle is ⅕ or 20 percent. The energy value of C can be updated to the next level at which the energy pulse is triggered. In this case, Kₕ can be set to 1000 kWh. Thus, every time the energy consumed reaches 1000 kWh, an energy measurement pulse can be generated. The sampling time T is multiplied by the duty cycle (⅕), giving the amount of time, T/5, which is waited before an energy measurement pulse is generated. Once that amount of time, T/5, has passed, the energy measurement pulse is generated. The remainder of the sampling period, 4/5T, is waited before sampling the next energy reading.

When the energy value A is less than the energy value C, then the condition that A is greater than or equal to C 84 is false. The sampling time T is waited for the next sampling 88. After the sampling time T has passed, then the next energy sample can be taken. The previous energy value of A is stored and redesignated as an energy value B. The currently sampled energy value is then stored and designated as an energy value A. Once again, it is determined whether A is greater than or equal to C 84. This will continue to loop until the condition that A is greater than or equal to C 84 is true; and thus the energy value A has reached the trigger threshold C. If the energy value A has reached the trigger threshold (i.e., A is greater than or equal to C), then the duty cycle is calculated and the energy measurement pulse is extrapolated as stated above.

While the present invention has been described with reference to certain preferred embodiments or methods, it is to be understood that the present invention is not limited to such specific embodiments or methods. Rather, it is the inventor's contention that the invention be understood and construed in its broadest meaning as reflected by the following claims. Thus, these claims are to be understood as incorporating not only the preferred methods described herein but all those other and further alterations and modifications as would be apparent to those of ordinary skilled in the art.

We claim:

1. A method for generating an energy pulse representative of a unit of consumed energy, comprising the steps of:
receiving a first energy measurement;
receiving a second energy measurement; and
if said second energy is greater than or equal to an energy threshold,
generating an energy measurement pulse as a function of said first energy measurement, said second energy measurement, and said energy threshold.

2. The method of claim 1 wherein in the generating step, a duty cycle, D, where D =(C−B)/(A−B), is calculated.

3. The method of claim 2 wherein there is a sampling time, T, and wherein in the generating step, the energy measurement pulse is outputted after waiting for a time period, T*D.

4. The method of claim 2 wherein the said energy threshold is increased by an energy level, Kₕ.

5. The method of claim 4 wherein there is a sampling time, T, and wherein in the generating step, the energy measurement pulse is outputted after waiting for a time period, T*D.

6. The method of claim 3 wherein in the generating step, waiting for an additional time period, T*(1−D) before repeating the process from the receiving a first energy measurement step.

7. The method of claim 5 wherein in the generating step, waiting for an additional time period, T*(1−D) before repeating the process from the receiving a first energy measurement step.

8. The method of claim 1 wherein after said if step, further comprising the step of:
if said second energy is less than the energy threshold, waiting for an additional time period, T before repeating the process from the receiving a first energy measurement step.

9. A method for generating an energy pulse representative of a unit of consumed energy, comprising the steps of:
receiving a first energy measurement;
receiving a second energy measurement;
if said second energy is greater than or equal to an energy threshold,
generating an energy measurement pulse as a function of said first energy measurement, said second energy measurement, and said energy threshold; and
if said second energy is less than the energy threshold,
waiting for an additional time period, T before repeating the process from the receiving a first energy measurement step.

10. The method of claim 9 wherein in the generating step, a duty cycle, D, where D=(C−B)/(A−B), is calculated.

11. The method of claim 10 wherein in the generating step, the energy measurement pulse is outputted after waiting for a time period, T*D.

12. The method of claim 10 wherein the said energy threshold is increased by an energy level, Kₕ.

13. The method of claim 12 wherein there is a sampling time, T, and wherein in the generating step, the energy measurement pulse is outputted after waiting for a time period, T*D.

14. The method of claim 11 wherein in the generating step, waiting for an additional time period, T*(1−D) before repeating the process from the receiving a first energy measurement step.

15. The method of claim 13 wherein in the generating step, waiting for an additional time period, T*(1−D) before repeating the process from the receiving a first energy measurement step.

16. A method for generating an energy pulse representative of a unit of consumed energy, comprising the steps of:
receiving a first energy measurement;
receiving a second energy measurement;
if said second energy is greater than or equal to an energy threshold,
generating an energy measurement pulse as a function of said first energy measurement, said second energy measurement, and said energy threshold, wherein a duty cycle, D, where D=(C−B)/(A−B), is calculated, wherein there is a sampling time, T, wherein the energy measurement pulse is outputted after waiting for a time period, T*D, wherein the said energy threshold is increased by an energy level, Kₕ, and wherein waiting for an additional time period, T*(1−D) before repeating the process from the receiving a first energy measurement step; and
if said second energy is less than the energy threshold,
waiting for the additional time period, T before repeating the process from the receiving a first energy measurement step.
